(19) United States
(12) Patent Application Publication
(10) Pub. No.: US 2009/0296445 A1
(43) Pub. Date: Dec. 3, 2009

(54) DIODE DECODER ARRAY WITH NON-SEQUENTIAL LAYOUT AND METHODS OF FORMING THE SAME

(76) Inventor: Daniel R. Shepard, North Hampton, NH (US)

Correspondence Address: GOODWIN PROCTER LLP;PATENT ADMINISTRATOR, 53 STATE STREET, EXCHANGE PLACE, BOSTON, MA, 02109-2881, US

(21) Appl. No.: 12/476,525

(22) Filed: Jun. 2, 2009

Related U.S. Application Data
(60) Provisional application No. 61/058,048, filed on Jun. 2, 2008.

(51) Int. Cl. G11C 5/02; H01S 4/00; G11C 8/10

(52) U.S. Cl. 365/51; 29/592.1; 365/230.06

(57) ABSTRACT

In various embodiments, an electronic circuit includes an array of locations each corresponding to an intersection of a row and a column, and a plurality of devices each disposed proximate one of the locations, wherein no more than ten contiguous locations lack a proximate device.

### CROSS-REFERENCE TO RELATED APPLICATION

This application claims priority to and the benefit of, and incorporates herein by reference in its entirety, U.S. Provisional Patent Application Ser. No. 61/058,048, which was filed on Jun. 2, 2008.

### TECHNICAL FIELD

In various embodiments, the present invention relates to the manufacture and processing of electronic devices, and more particularly to methods for improving process yield by reducing variation during wafer processing.

### BACKGROUND

High-density storage devices achieve great bit-packing densities when they incorporate an array of diodes as storage elements. In such devices, it may be advantageous to implement row and column decoding with a sparsely populated diode array. Such a row and column decoder is described in U.S. Pat. No. 5,673,218 by Shepard (“the '218 patent”), the entire disclosure of which is herein incorporated by reference. Diode-based decoder arrays are typically only approximately 50% “populated” with diodes, as both the address bits and their complements are included and either one or the other (but not both) are connected to the rest of the array via a diode.

Problems may arise during the manufacturing of diode-decoded diode storage arrays as a result of the different densities of the diodes in the decoder array pattern. In particular, during chemical-mechanical polishing (CMP), when the loading density of one part of the wafer differs from that of another part, different polishing rates may occur. Thus, portions of the array will be under-polished (and thus improperly processed), and portions of the array will be over-polished (and hence inoperative). Moreover, the use of polish-stop layers to promote process uniformity may be unfeasible for certain layouts and increases the cost and complexity of device processing. Thus, the need exists for device layouts designed to promote processing uniformity and yield.

### SUMMARY

Embodiments of the present invention include techniques for laying out storage arrays and decoders, e.g., non-sequential address ordering, that promote process uniformity and thus increase device yield.

In an aspect, embodiments of the invention feature an electronic circuit including an array of locations each corresponding to an intersection of a row and a column. The circuit includes a plurality of devices each disposed proximate (e.g., nearest to, or even directly disposed at) a location. No more than ten contiguous locations lack a device. In some embodiments, no more than four contiguous locations lack a device. The rows of the array may be ordered non-sequentially. Each device may be a diode, an NMOS transistor, or a PMOS transistor. The array of locations may be disposed within a decoder circuit of a memory device.

In another aspect, embodiments of the invention feature an electronic circuit including a memory array. The memory array includes or consists essentially of a plurality of memory rows and a plurality of memory columns intersecting the plurality of memory rows. A row decoder is connected to the plurality of memory rows and a column decoder is connected to the plurality of memory columns. Each of the row and column decoders includes or consists essentially of an array of locations each corresponding to an intersection of a row and a column, and a plurality of devices each proximate a location. No more than ten contiguous locations lack a device. In some embodiments, no more than four contiguous locations in the row decoder and/or the column decoder lack a device. The memory array may include a plurality of current-steering devices each disposed proximate an intersection of a memory row and a memory column. Each current-steering device may include or consist essentially of a diode.

In a further aspect, embodiments of the invention feature a method for forming an electronic device. An array of bits, a row decoder array connected to the array of bits, and a column decoder connected to the array of bits are formed, and the row decoder array includes no more than ten contiguous row address locations that lack a row decoder device. Forming the row decoder array may include ordering rows of the row decoder array non-sequentially. In some embodiments, the row decoder array includes no more than four contiguous row address locations that lack a row decoder device. The column decoder array may include no more than ten contiguous column address locations that lack a column decoder device. Forming the column decoder array may include ordering column of the column decoder array non-sequentially. In some embodiments, the column decoder array includes no more than four contiguous column address locations that lack a column decoder device. Forming the row decoder array may include forming a dielectric layer over row address locations within the row decoder array and removing a portion of the dielectric layer, where the remaining portion of the dielectric layer over each row address location is substantially uniform. Removing the portion of the dielectric layer may include or consist essentially of chemical-mechanical polishing.

In yet another aspect, embodiments of the invention feature a method for forming an electronic device. A first array of locations is formed on a first substrate. A portion of a first layer disposed over the first array of locations is removed, whereby the remaining portion of the first layer has a first uniformity. A second array of locations is formed on a second substrate. A portion of a second layer disposed over the second array of locations is removed, whereby the remaining portion of the second layer has a second uniformity greater than the first uniformity. A row order of the first array of locations is different from a row order of the second array of locations. The row order of the first array of locations may be substantially sequential and the row order of the second array of locations may be substantially non-sequential. Each of the first and second layers may include or consist essentially of a dielectric material. Removing the portions of the first and second layers may include or consist essentially of chemical-mechanical polishing.

In yet a further aspect, embodiments of the invention feature a method for forming an electronic device organized as an array with crossing points, devices being present at only some of the crossing points and at varying densities. The devices are reorganized such that the array contains open areas lacking devices; the open areas are no greater in size than 2×2. The array is polished, whereby the polished array has a substantially planar uniformity owing to the reorganized devices.

These and other objects, along with advantages and features of the present invention herein disclosed, will become more apparent through reference to the following description, the accompanying drawings, and the claims. Furthermore, it is to be understood that the features of the various embodiments described herein are not mutually exclusive and may exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1 schematically depicts a memory device;

FIG. 2 schematically depicts a typical layout of diodes in a diode decoder;

FIGS. 3A and 3B are enlarged cross-sectional illustrations of the processing of a prior-art diode decoder;

FIG. 4 schematically depicts a layout of diodes in a diode decoder according to embodiments of the present invention; and

FIGS. 5A and 5B are enlarged cross-sectional illustrations of the processing of a diode decoder in accordance with various embodiments of the invention.

### DETAILED DESCRIPTION

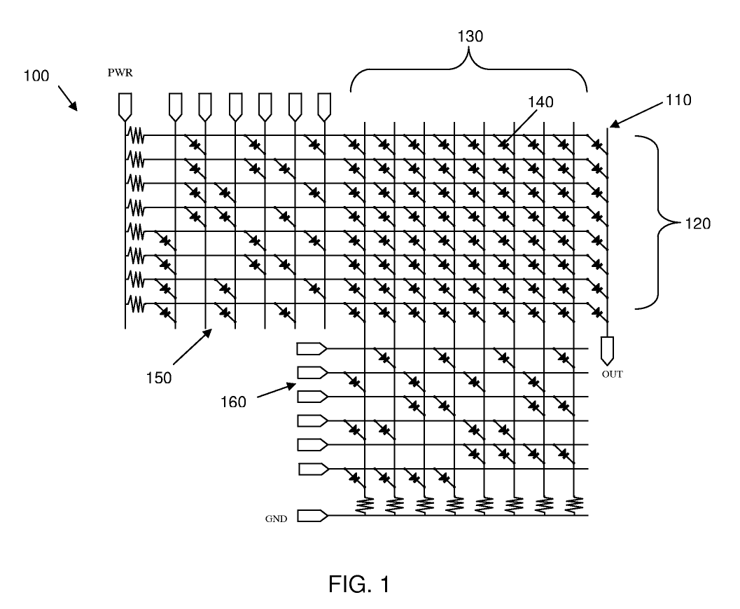

FIG. 1 depicts an exemplary memory device 100 compatible with embodiments of the present invention. Memory device 100 includes a memory array 110 of memory locations, or bits, defined by the intersection of memory rows 120 and memory columns 130. A storage element 140, which may include or consist essentially of, e.g., a diode or other current-steering device, is disposed proximate at least some of the memory locations. In various embodiments, a storage element 140 is present proximate each of the memory locations in order to prevent the propagation of “back currents” through the memory array 110. Memory device 100 also may include a row decoder 150 and/or a column decoder 160. Each of row decoder 150 and column decoder 160 preferably includes or consists essentially of a patterned array of non-linear elements such as diodes or other rectifying devices. While decoders are typically described herein as “diode decoders,” it is understood that such decoders may include non-linear elements other than diodes, e.g., NMOS transistors and/or PMOS transistors.

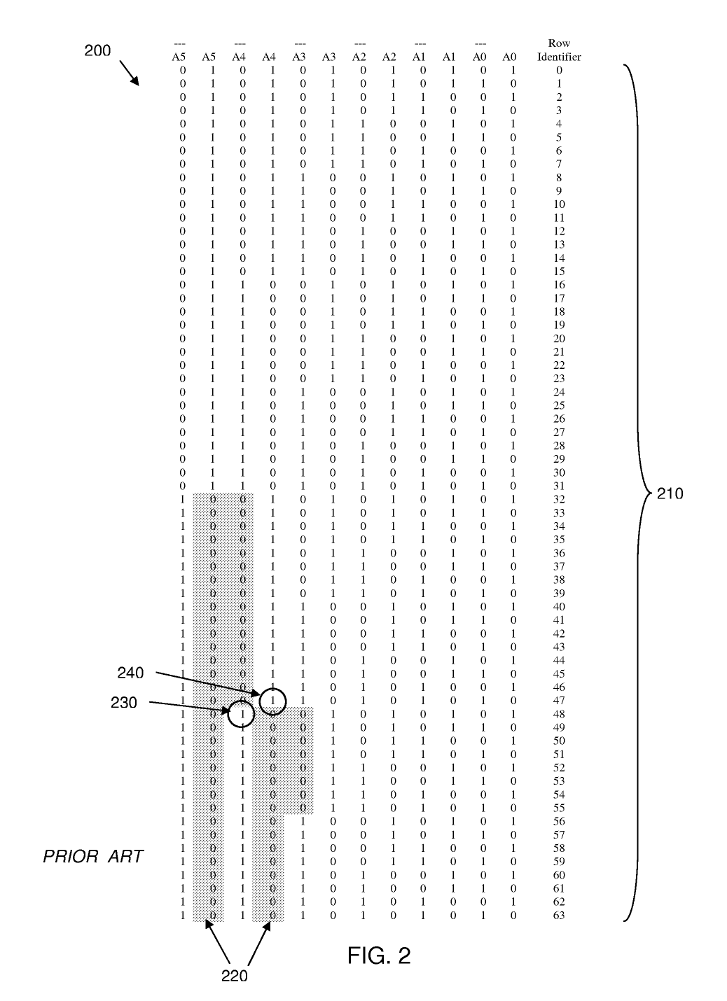

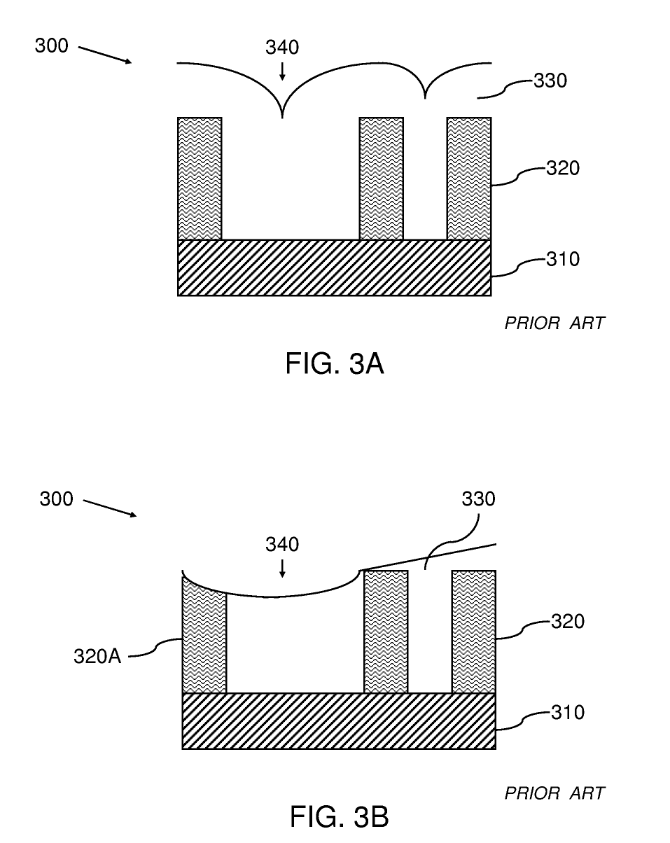

FIG. 2 is a schematic depiction of the layout of diodes within a diode decoder 200 in which a “1” represents the location of a diode within the decoder (i.e., proximate a row-column intersection, as described above) and a “0” represents a row-column intersection without a diode connection. During manufacture, a substrate with diodes laid out as shown in FIG. 2 may have an insulating material (e.g., a dielectric such as an oxide) deposited over and between the diodes; this oxide layer may then require planarization, e.g., polishing by CMP. This is often done, particularly when diode geometries are scaled into the nano-scale, to provide a more planar surface to better facilitate subsequent photolithography steps. CMP may also be performed to expose the tops of the diodes while leaving the dielectric fill between the diodes for interdevice isolation. The processing of devices having layouts like those depicted in FIG. 2 is described below with reference to FIGS. 3A and 3B.

The diodes in the decoder pattern translate the complementary address pairs into unique addresses that are typically ordered sequentially. As shown in FIG. 2, the rows 210 of diode decoder 200 are numbered in sequential order, leading to discrete areas that are nearly or completely filled with devices and areas which are sparsely populated (e.g., sparse area 220 described below). With such a pattern of areas of different device “population,” processing, e.g., planarization, of the different areas may be non-uniform. Furthermore, when these areas are combined with the dense pattern of the storage area in which there are few or no sparse areas, the non-uniformity may be further increased. Non-uniformity in planarization may result in over-polishing of some areas, in which devices may be shorted together or even destroyed, and/or under-polishing, in which an insufficient amount of the dielectric fill material is removed to properly contact the underlying devices.

Sparse area 220 (represented by the shaded areas in FIG. 2) is an area substantially free of diodes. On row 48 of diode decoder 200, diode 230 is “exposed” on three sides due to the absence of devices on those sides. During planarization by, e.g., CMP, the direction of the polishing head (and thus the direction of the polishing action) changes almost continuously. Thus, at times, the polishing direction will correspond to the direction corresponding to the top of FIG. 2, moving towards the bottom. At these times, the polishing slurry will generally be forced down into the long channel of sparse area 220 above exposed diode 230 toward exposed diode 230, thus increasing the local planarization rate of materials near or at exposed diode 230. The fact that exposed diode 230 is exposed on three sides may additionally increase the local planarization rate near exposed diode 230. Thus, exposed diode 230 (and other nearby devices, e.g., exposed diode 240) will be planarized at a higher rate. Such devices are likely to be over-polished and hence exhibit differences in electrical performance (from that of devices experiencing less planarization) or may even become inoperative.

FIGS. 3A and 3B depict the processing of a prior-art diode decoder 300. Referring to FIG. 3A, diodes 320 are formed over a substrate 310, and a layer 330 is formed over the diodes 320. Layer 330 may include or consist essentially of, e.g., a dielectric material such as silicon nitride or silicon dioxide. As shown in FIG. 3A, the distribution of diodes 320 may be substantially non-uniform, leading to the formation of at least one sparse area 340. Referring to FIG. 3B, layer 330 may then be planarized by, e.g., CMP. The presence of sparse area 340 leads to significant non-uniformity in the local polish rate during planarization rate and, thus, significant non-uniformity in the amount of layer 330 remaining across substrate 310. As shown in FIG. 3B, an exposed diode 320A may even be partially removed (rendering it inoperative or having diminished electrical performance) during the planarization step. Other diodes 320 may have various amounts of layer 330 disposed thereover after planarization, leading to further complications in processing or differences in electrical performance.

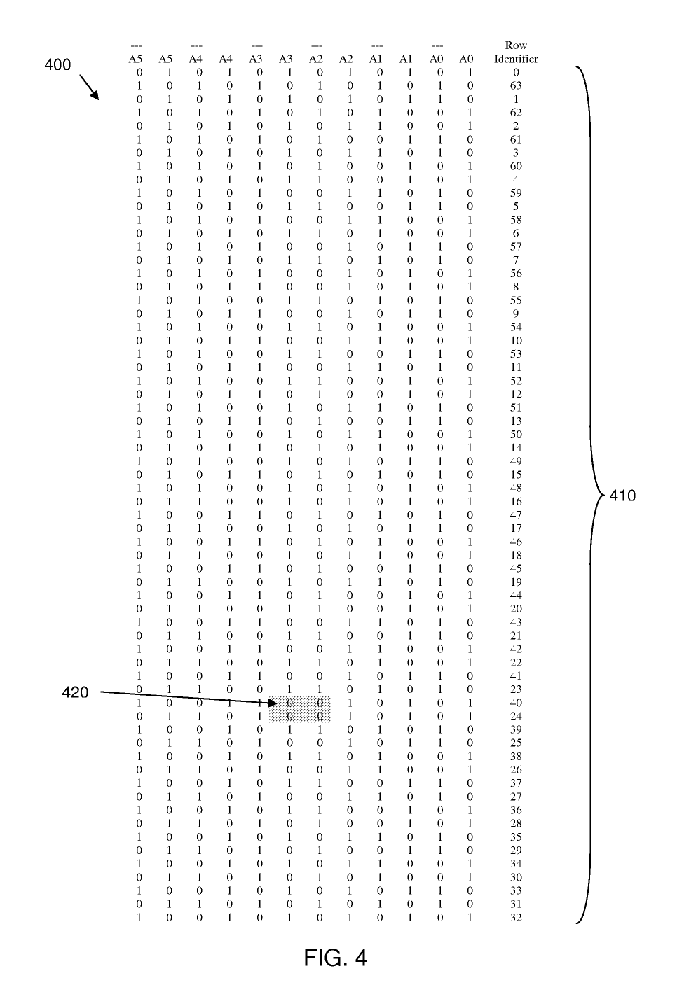

Embodiments of the present invention facilitate uniformity in processing, and therefore, electrical performance, of devices in, e.g., diode decoders, by distributing the locations of the diodes more evenly throughout the device. FIG. 4 illustrates a diode decoder 400 designed according to embodiments of the present invention. The preferred, more even distribution of diodes eliminates large sparse areas (e.g., larger than approximately ten devices, or even larger than approximately four devices) that are substantially free of devices. As shown in FIG. 4, in embodiments of the present invention, the re-sequencing of the rows 410 of diode decoder 400 is non-sequential. The re-sequencing may be accomplished in any manner that results in breaking up the long-range order of the binary pattern typical of a diode decoder (e.g., diode decoder 200), that results in discrete populated areas and sparse areas. Generally, the row (or column, in some embodiments) distribution is mixed to make the rows substantially non-sequential, thus eliminating large sparse areas lacking devices therein.

In one embodiment, the rows are re-ordered in the exemplary fashion illustrated in FIG. 4. In FIG. 4, rows 410, having initially had the order depicted in FIG. 2 (as rows 210, with sequential row identifiers 0-63), have been re-ordered in the sequence 0, 63, 1, 62, . . . 31, 32. That is, rows from the end of the sequential sequence have been inserted between the rows at the beginning of the sequence, thus “interleaving” the first half and the second half of the rows. With this ordering of rows 410 in the example depicted in FIG. 4, the largest open (i.e., diode-free) area corresponds to sparse area 420, which is only four contiguous locations in size. Other orderings are possible that will also result in sparse areas of no more than 2×2 device locations. Also, other orderings that will sufficiently distribute the diodes in the pattern are possible. These may result in open areas larger than 2×2 but smaller than the sparse areas 220 that may cause loading problems as depicted in FIG. 2. In a preferred embodiment, any sparse or open areas in the diode array are less than ten address locations. Another exemplary re-ordering may include interleaving three groups of rows, e.g., a sequence beginning 0, 31, 63, . . . . In other embodiments, rows are be re-ordered in a random or pseudo-random fashion.

In another embodiment, sparse areas in the array are identified, and rows corresponding to the sparse areas are interleaved with the other rows of the array. For example, sparse areas 220 depicted in FIG. 2 span rows 32-63, so these rows may be interleaved with the remaining rows (rows 0-31) in any fashion that eliminates large sparse areas. Furthermore, if sparse-area rows are interleaved with other rows in the array and sparse areas larger than those desired are still present, this process may be repeated until sparse areas are minimized or eliminated. In another embodiment, the rows are re-ordered with lesser granularity. That is, row pairs from the end of the sequential sequence may be inserted between every two or more rows at the beginning of the sequence, thus “interleaving” groups of rows from the first half with groups of rows from the second half of the rows, where these two groupings may be equally or differently sized. Even a pseudorandom ordering may exhibit improved CMP performance compared to the pure sequential ordering.

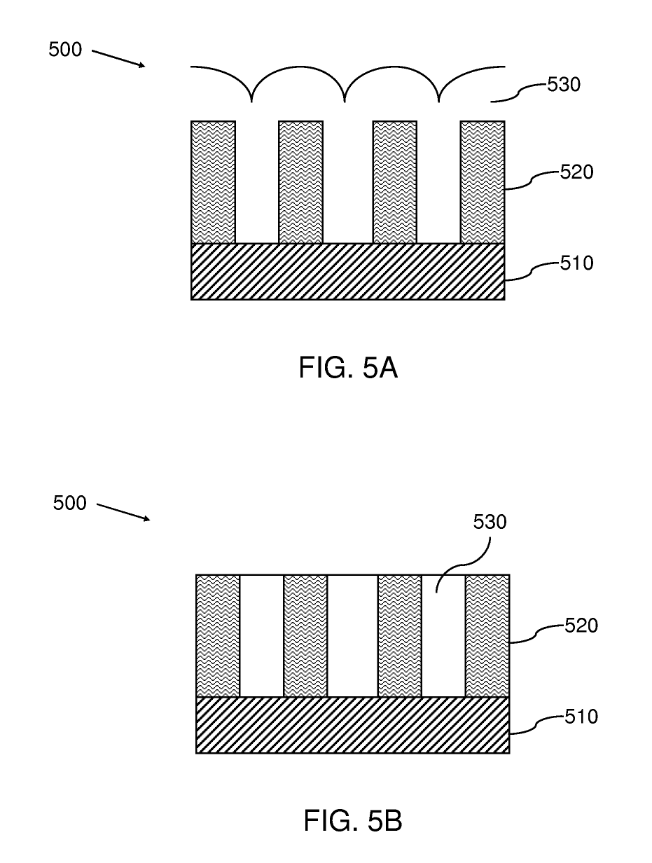

FIGS. 5A and 5B depict the processing of a diode decoder 500 designed according to embodiments of the present invention. Referring to FIG. 5A, diodes 520 are formed over a substrate 510, and a layer 530 is formed over the diodes 520. Layer 530 may include or consist essentially of, e.g., a dielectric material such as silicon nitride or silicon dioxide. As shown in FIG. 5A, the distribution of diodes 520 may be substantially uniform due to the re-sequencing of, e.g., rows, as described above with reference to FIG. 4. Thus, diode decoder 500 is substantially free of sparse areas, and diodes 520 are substantially uniformly distributed over substrate 510. Referring to FIG. 5B, layer 530 may then be planarized by, e.g., CMP. The uniformity of the distribution of diodes 520 results in a substantially uniform polish rate, and thus, after planarization, the amount of layer 530 remaining over substrate 510 is substantially uniform. Although FIG. 5B depicts a top surface of layer 530 as being substantially coplanar with the top surfaces of diodes 520, in various embodiments, these surfaces may not be coplanar. The uniformity of layer 530 after planarization facilitates the fabrication of diodes 520 having substantially uniform electrical characteristics, and increases the overall device yield of diode decoder 500.

Variations on the present invention include ordering other patterns non-sequentially (for example, the column diode decoder diodes). Furthermore, embodiments of the present invention apply to decoder designs other than diode decoder designs, including transistor-based designs incorporating NMOS, PMOS, CMOS, or other technologies. Indeed, embodiments of the invention are applicable anywhere a pattern results in uneven loading to a processing step (such as polishing) where the sequence order can be varied to better distribute the devices in the pattern.

Embodiments of the present invention may be utilized in memory devices that include cross-point memory arrays, e.g., memory arrays such as those described in U.S. Pat. No. 5,889,694 or U.S. patent application Ser. Nos. 11/729,423 or 11/926,778, the entire disclosure of each of which is hereby incorporated by reference. The memory array may be one of a plurality of “tiles” or sub-arrays of a larger memory array, or may be a layer (or portion of a layer) in a three-dimensional memory array that may be fabricated in accordance with U.S. Pat. No. 6,956,757 to Shepard, the entire disclosure of which is hereby incorporated by reference. The storage cells of the memory array may include at least one transistor, field emitter, diode, four-layer diode, gated four-layer diode (thyristor), and/or any other device that conducts current asymmetrically at a given applied voltage. The storage elements may be fuses, antifuses, and/or devices including a resistive-change material, which may be a phase-change material such as a chalcogenide (or other material capable of programmably exhibiting one of two or more resistance values). The resistive-change material may be placed in series with a diode (or other rectifier or current-steering device) at a memory cell location. The resistive-change material may include or consist essentially of an alloy of germanium, antimony, and tellurium (GST).

The storage element may even include a field-emitter programming element whose resistance and/or volume is changeable and programmable, e.g., a device described in U.S. patent application Ser. Nos. 11/707,739 or 12/339,696, the entire disclosures of which are hereby incorporated by reference. The storage cells and/or storage elements may be present at or near one or more intersections between a row and a column, and may even be present at all such intersections. In an embodiment, various intersections may even include different types of storage cells or elements. In various embodiments, memory devices may include one or more layers of storage cells and/or storage elements, and the memory array(s) of any layer may include one or more sub-arrays or tiles.

Memory devices constructed according to embodiments of the present invention will find applicability in such areas as storing digital text, digital books, digital music, digital audio, digital photography (wherein one or more digital still images can be stored including sequences of digital images), digital video, and digital cartography (wherein one or more digital maps can be stored), as well as any combinations thereof. These devices may be embedded, removable, or removable and interchangeable among devices. They may be packaged in any variety of industry standard form factors including Compact Flash, Secure Digital, MultiMedia Cards, PCMCIA Cards, Memory Stick, any of a large variety of integrated circuit packages including Ball Grid Arrays, Dual In-Line Packages (DIPs), SOICs, PLCC, TQFP's and the like, as well as in custom designed packages. These packages may contain just the memory chip, multiple memory chips, one or more memory chips along with a controller or other logic devices or other storage devices such as PLDs, PLAs, micro-controllers, microprocessors, controller chips, or chip-sets or other custom or standard circuitry.

Memory devices constructed according to embodiments of the present invention will also find applicability in such areas as solid state disk drives (SSD). These SSDs may include one or more memory devices and may also be combined with a controller device (including, e.g., control circuitry as described above).

The terms and expressions employed herein are used as terms and expressions of description and not of limitation, and there is no intention, in the use of such terms and expressions, of excluding any equivalents of the features shown and described or portions thereof. In addition, having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1. An electronic circuit comprising:
an array of locations each corresponding to an intersection of a row and a column; and
a plurality of devices each disposed proximate one of the locations,
wherein no more than ten contiguous locations lack a proximate device.

2. The electronic circuit of claim 1, wherein no more than four contiguous locations lack a proximate device.

3. The electronic circuit of claim 1, wherein rows of the array are ordered non-sequentially.

4. The electronic circuit of claim 1, wherein each device is selected from the group consisting of a diode, an NMOS transistor, and a PMOS transistor.

5. The electronic circuit of claim 1, wherein the array of locations is disposed within a decoder circuit of a memory device.

6. An electronic circuit comprising:
a memory array comprising a plurality of memory rows and a plurality of memory columns intersecting the plurality of memory rows;
a row decoder connected to the plurality of memory rows; and
a column decoder connected to the plurality of memory columns,
wherein each of the row and column decoders comprises:
an array of locations each corresponding to an intersection of a row and a column;
a plurality of devices each proximate one of the locations,
wherein no more than ten contiguous locations lack a proximate device.

7. The electronic circuit of claim 6, wherein no more than four contiguous locations in the row decoder lack a proximate device.

8. The electronic circuit of claim 6, wherein no more than four contiguous locations in the column decoder lack a proximate device.

9. The electronic circuit of claim 6, wherein the memory array comprises a plurality of current-steering devices each disposed proximate an intersection of a memory row and a memory column.

10. The electronic circuit of claim 9, wherein each current-steering device comprises a diode.

11. A method for forming an electronic device, the method comprising the steps of:
forming an array of bits;
forming a row decoder array connected to the array of bits; and
forming a column decoder array connected to the array of bits,
wherein the row decoder array comprises no more than ten contiguous row address locations that lack a row decoder device.

12. The method of claim 11, wherein forming the row decoder array comprises ordering rows of the row decoder array non-sequentially.

13. The method of claim 11, wherein the row decoder array comprises no more than four contiguous row address locations that lack a row decoder device.

14. The method of claim 11, wherein the column decoder array comprises no more than ten contiguous column address locations that lack a column decoder device.

15. The method of claim 11, wherein forming the column decoder array comprises ordering rows of the column decoder array non-sequentially.

16. The method of claim 11, wherein the column decoder array comprises no more than four contiguous column address locations that lack a column decoder device.

17. The method of claim 11, wherein forming the row decoder array comprises:
forming a dielectric layer over row address locations within the row decoder array, and
removing a portion of the dielectric layer,
wherein a remaining portion of the dielectric layer over each row address location is substantially uniform.

18. The method of claim 17, wherein removing at least a portion of the dielectric layer comprises chemical-mechanical polishing.

19. A method for forming an electronic device, the method comprising the steps of:
forming an first array of locations on a first substrate;
removing a portion of a first layer disposed over the first array of locations, whereby a remaining portion of the first layer has a first uniformity;
forming a second array of locations on a second substrate; and
removing a portion of a second layer disposed over the second array of locations, whereby a remaining portion of the second layer has a second uniformity greater than the first uniformity,
wherein a row order of the first array of locations is different from a row order of the second array of locations.

20. The method of claim 19, wherein the row order of the first array of locations is substantially sequential and the row order of the second array of locations is substantially non-sequential.

21. The method of claim 19, wherein each of the first and second layers comprises a dielectric material.

22. The method of claim 19, wherein removing the at least a portions of the first and second layers comprises chemical-mechanical polishing.

23. A method for forming an electronic circuit comprising a plurality of devices and organized as an array with crossing points, devices being present at only some of the crossing points and at varying densities, the method comprising the steps of:
reorganizing the devices such that the array contains open areas lacking devices, the open areas being no greater in size than 2×2; and
polishing the array, whereby the polished array has substantially planar uniformity owing to the reorganized devices.
